(19) United States
(12) Patent Application Publication
(10) Pub. No.: US 2010/0296280 A1
(43) Pub. Date: Nov. 25, 2010

(54) White-light LED Device and Illuminating Method of the same

(75) Inventors: Chiu-Chung YANG, TAICHUNG CITY (TW); Chien-Sheng HUANG, TAINAN CITY (TW); Kai-Jen YANG, TAICHUNG CITY (TW); Su-Hon LIN, KEELUNG CITY (TW); Ming-Hwa SHEU, TAICHUNG CITY (TW)

Correspondence Address: BRIAN M. MCINNIS, 12th Floor, Ruttonjee House, 11 Duddell Street, Hong Kong, HK

(73) Assignee: Kai-Jen YANG, TAICHUNG CITY (TW)

(21) Appl. No.: 12/782,664

(22) Filed: May 18, 2010

(30) Foreign Application Priority Data
May 20, 2009 (TW) 98116754

(51) Int. Cl. F21V 9/00; H01L 33/44

(52) U.S. Cl. 362/231; 257/89; 257/E33.061

(57) ABSTRACT

A white-light LED device is disclosed. The white-light LED device includes a base, at least one purple light source and at least one yellow light source. The purple light source and the yellow light source are disposed on the base, and they are adjacent to each other such that the illuminations are mixed to produce white light. An illumination method is also disclosed. The illumination method includes the following steps: At least one purple light source and at least one yellow light source are disposed on a base. The illuminations of the yellow light source and the purple light source are mixed to produce white light.

### RELATED APPLICATIONS

This application claims priority to Taiwan Patent Application Number 98116754, filed May 20, 2009, which is herein incorporated by reference.

### BACKGROUND

1. Technical Field

The present disclosure relates to an LED module having a plurality of LEDs, which comprises mixed-light LEDs and additional LEDs.

2. Description of Related Art

White-light LED illuminating devices had been developed due to its light weight and low power consumption. There are three ways to generate white light via the LED. The first way is by mixing the tri-chromatic lights, i.e. the RGB lights. However, since the threshold voltages of the RGB light LEDs differ from each other, the required circuit to drive the LEDs is expensive and complicate.

The second way to generate white light is using the phosphor. However, the color distortion and power consumption are large. The third way to generate white light is forming a blue light LED on a ZnSe substrate. The blue light LED provides a blue light and the ZnSe substrate generates a yellow light. The white light is generated by mixing the blue light and the yellow light. The second and third ways to produce white light require no complicated controlling circuit, but still suffer a great deal of color distortion.

### SUMMARY

In one embodiment of the disclosure, a white-light LED device is disclosed. The white-light LED device includes a base, at least one purple light source and at least one yellow light source. The purple light source is disposed on the base. The yellow light source is also disposed on the base. The yellow light source is adjacent to the purple light source, such that the illumination of the yellow light source and the illumination of the purple light source are mixed to produce white light.

In another embodiment of the disclosure, an illumination method is disclosed. The illumination method includes the following steps: At least one purple light source and at least one yellow light source are disposed on a base. The illumination of the yellow light source and the illumination of the purple light source are mixed to produce white light.

### BRIEF DESCRIPTION OF THE DRAWINGS

The disclosure can be more fully understood by reading the following detailed description of the embodiments, with reference made to the accompanying drawings as follows:

FIG. 1 is a schematic view of a white-light LED device of one embodiment of the disclosure.

FIG. 2 depicts the project locations of the purple light, the yellow light and the adjusting light in FIG. 1.

FIG. 3 depicts many scattering particles are mixed in the encapsulant in FIG. 1.

FIG. 4 is a schematic view of a white-light LED device of another embodiment of the disclosure.

FIG. 5 depicts another topology in FIG. 4.

FIG. 6 depicts still another topology in FIG. 4.

FIG. 7 is a step flowchart of an illumination method of one embodiment of the disclosure.

### DETAILED DESCRIPTION

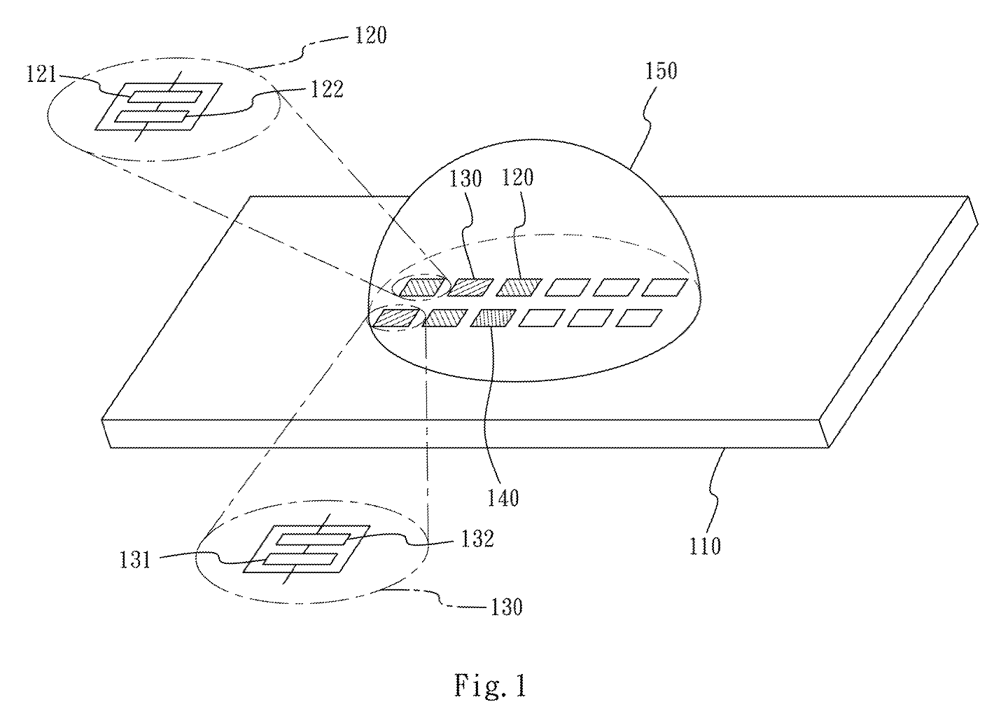

FIG. 1 is a schematic view of a white-light LED device of one embodiment of the disclosure. The white-light LED device 100 includes a base 110, at least one purple light source 120 and at least one yellow light source 130. The purple light source 120 and the yellow light source 130 are disposed on the base 110, and they are adjacent to each other such that their illuminations are mixed to produce white light.

In another embodiment of the disclosure, the white-light LED device 100 further includes an adjusting light source 140 disposed on the base 110. The adjusting light source 140 is applied to adjust the color temperature of the white light. In detail, the spectrum of the adjusting light source is 560 nm-610 nm, 470 nm-500 nm or 596 nm-780 nm.

In still another embodiment of the disclosure, the white-light LED device 100 further includes an encapsulant 150 and the light sources are achieved by dies encapsulated therein. In detail, the encapsulant 150 is disposed around the purple light source 120, the yellow light source 130, and the adjusting light source 140.

The purple light source 120 is achieved by electrically connecting a red light LED die 121 and a blue light LED die 122 in series, and the yellow light source 130 is achieved by electrically connecting a green light LED die 131 and a red light LED die 132 in series. In detail, the threshold voltage of the red light LED die is about 2 V, and the threshold voltage of the blue light LED die is about 3 V. The purple light source 120 which is achieved by connecting a red light LED die 121 and a blue light LED die 122 in series requires a threshold voltage about 5 V. Similarly, the threshold voltage of the yellow light source 130 is also about 5 V. Therefore, the white-light LED device 100 of the embodiment requires no complicated controlling circuit and also provides good color rendering index.

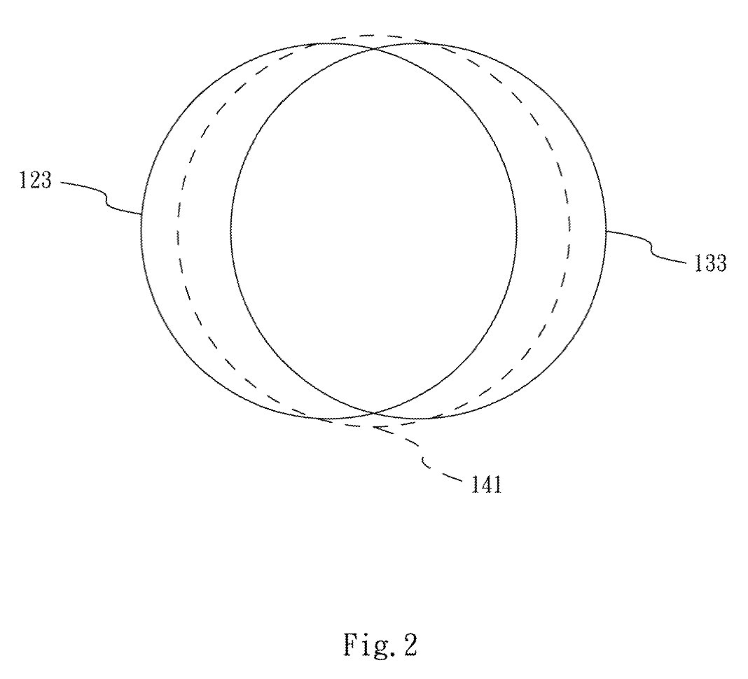

FIG. 2 depicts the project locations of the purple light, the yellow light and the adjusting light in FIG. 1. The purple light illuminating region 123 and the yellow light illuminating region 133 are overlapped in most part, and the adjusting light illuminating region 141 is located approximately between them.

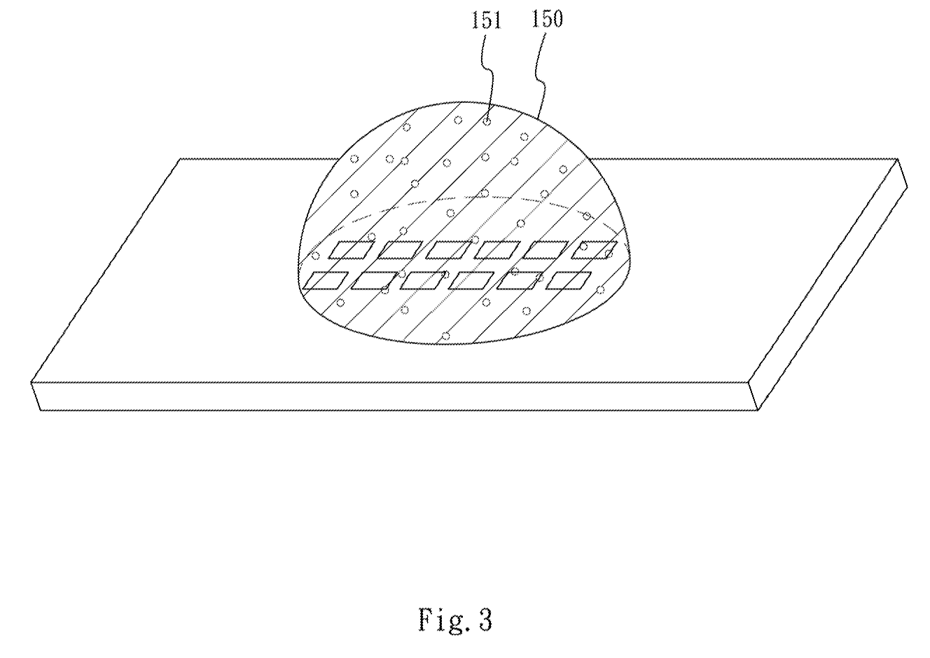

FIG. 3 depicts many scattering particles are mixed in the encapsulant in FIG. 1. In FIG. 3, many scattering particles 151 are mixed in the encapsulant 150 to make the spectrum of the white light more uniform. The encapsulant 150 can be achieved by an epoxy resin material, a glass packaging material or a silicon encapsulation material. Additionally, a dispersant is also can be added in the encapsulant 150 to make the scattering particles 151 well mixed. Furthermore, a lens can be applied to control the project direction of the white-light LED device 100.

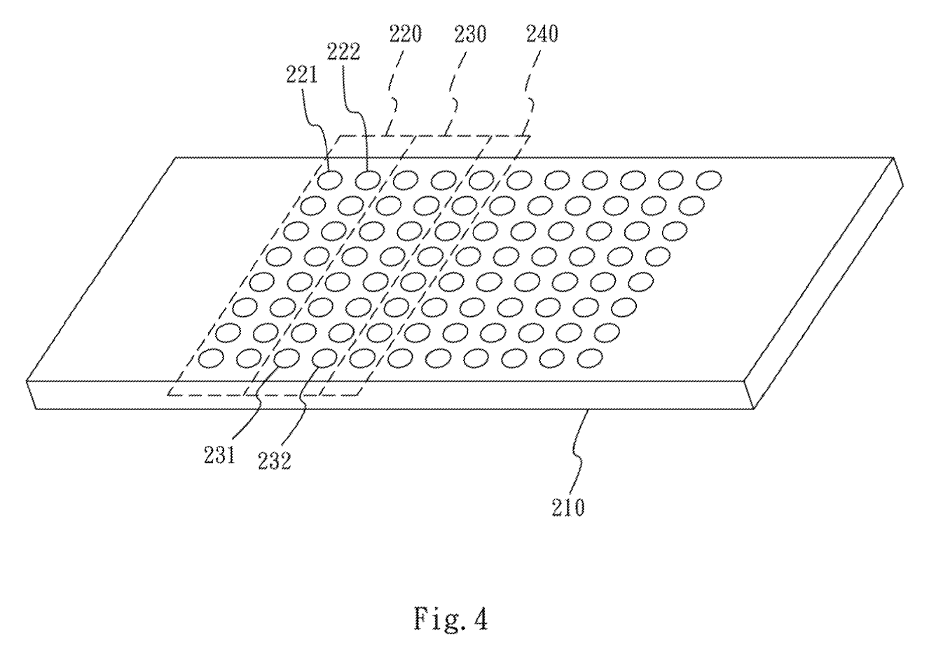

FIG. 4 is a schematic view of a white-light LED device of another embodiment of the disclosure. In FIG. 4, the purple light source 220 is achieved by at least one red light LED chip 221 and at least one blue light LED chip 222. The yellow light source 230 is achieved by at least one green light LED chip 231 and at least one red light LED chip 232. The LED chips can be the LED dual in-line package (DIP) or the LED surface mounted device (SMD). The purple light source 220 includes many LED chips can be merged together as a module, and thus detachably connected to the base 210 such as a circuit board. Similarly, the yellow light source 230 and the adjusting light source 240 are also detachably connected to the base 210.

In FIG. 4, the red light LED chip 221 and the blue light LED chip 222 are connected in series to provide the purple light source 220 a threshold voltage, and the green light LED chip 231 and the red light LED chip 232 are also connected in series to provide the yellow light source 230 an approximate threshold voltage. The adjusting light source 240 includes at least one red, green, blue, yellow or cyan light LED chip. Therefore, the illuminations of the color LED chips are mixed to generate the white light with good color rendering index. On the other hand, the light sources having approximate threshold voltages prevent the complicated and expensive controlling circuit.

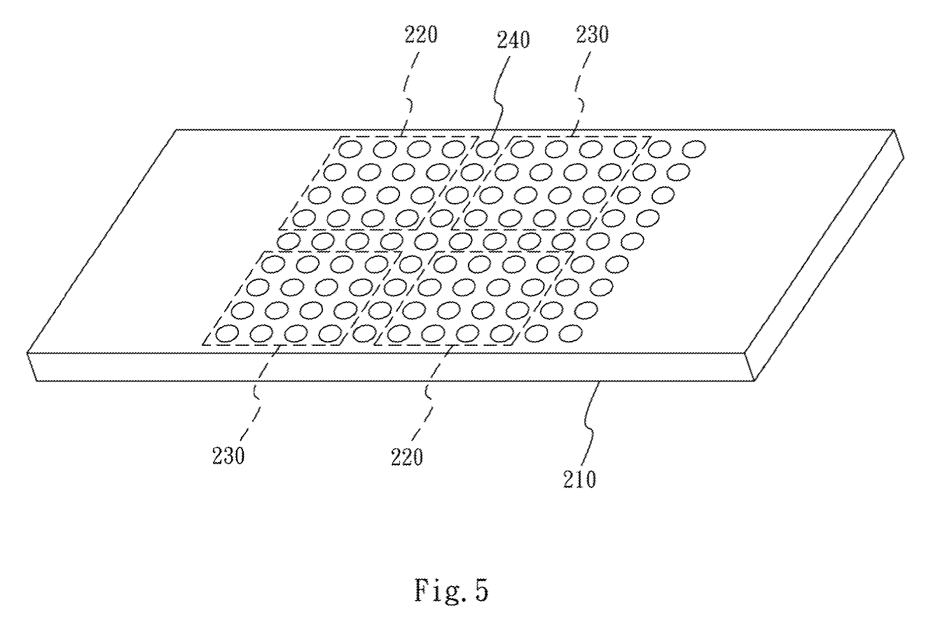

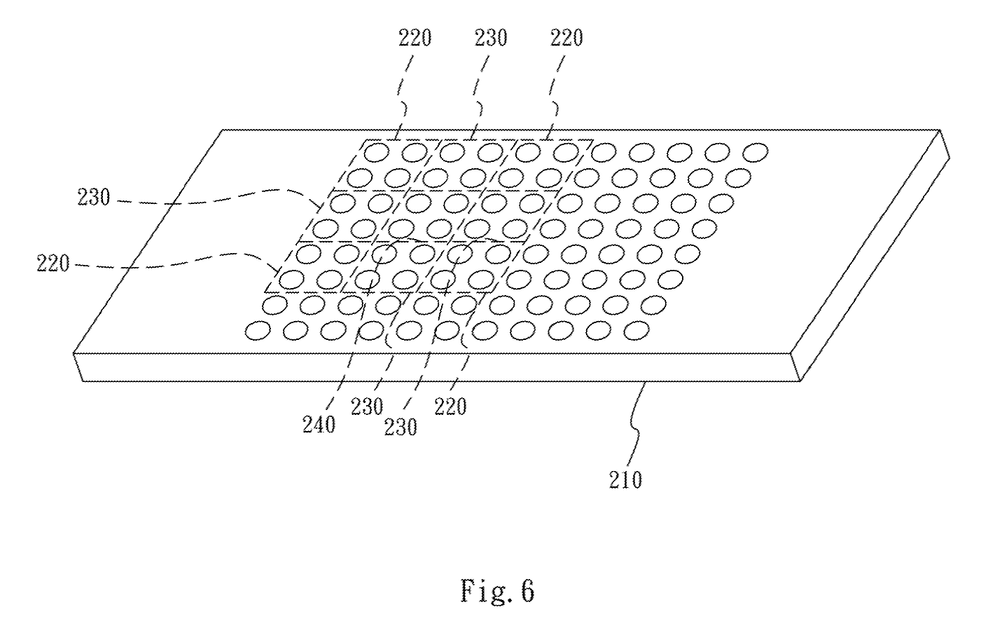

FIG. 5 depicts another topology in FIG. 4. In FIG. 5, the light sources can be arranged as an array. The adjusting light source 240 is arranged between each block. FIG. 6 depicts still another topology in FIG. 4. In FIG. 6, the yellow light sources 230 and the purple light sources 220 are interlaced around an adjusting light source 240.

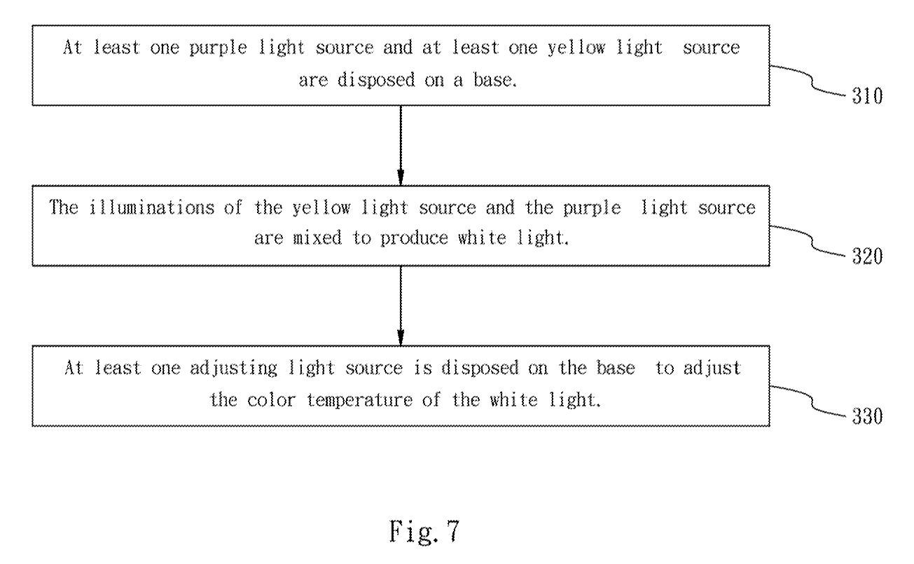

FIG. 7 is a step flowchart of an illumination method of one embodiment of the disclosure. The method includes the following steps: First, as shown in step 310, at least one purple light source and at least one yellow light source are disposed on a base. Second, as shown in step 320, the illuminations of the yellow light source and the purple light source are mixed to produce white light. Third, as shown in step 330, at least one adjusting light source is disposed on the base to adjust the color temperature of the white light.

In another embodiment of the illumination method, at least one red light LED die and at least one blue light LED die are connected in series to form the purple light source. Similarly, at least one green light LED die and at least one red light LED die are connected in series to form the yellow light source. In still another embodiment of the illumination method, the purple light source, the yellow light source, and the adjusting light source are encapsulated in an encapsulant.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A white-light LED device comprising:
a base;
at least one purple light source disposed on the base; and
at least one yellow light source disposed on the base and adjacent to the purple light source, such that the illumination of the yellow light source and the illumination of the purple light source are mixed to produce white light.

2. The white-light LED device of claim 1, further comprising:
an adjusting light source disposed on the base for adjusting the color temperature of the white light.

3. The white-light LED device of claim 2, wherein the spectrum of the adjusting light source is 560 nm-610 nm.

4. The white-light LED device of claim 2, wherein the spectrum of the adjusting light source is 470 nm-500 nm.

5. The white-light LED device of claim 2, wherein the spectrum of the adjusting light source is 596 nm-780 nm.

6. The white-light LED device of claim 2, further comprising:
an encapsulant disposed around the purple light source, the yellow light source, and the adjusting light source.

7. The white-light LED device of claim 6, further comprising:
a plurality of scattering particles mixed in the encapsulant.

8. The white-light LED device of claim 6, wherein the purple light source comprises a red light LED die and a blue light LED die connected in series.

9. The white-light LED device of claim 6, wherein the yellow light source comprises a green light LED die and a red light LED die connected in series.

10. The white-light LED device of claim 2, wherein the adjusting light source is detachably connected to the base.

11. The white-light LED device of claim 1, wherein the purple light source is detachably connected to the base.

12. The white-light LED device of claim 1, wherein the yellow light source is detachably connected to the base.

13. The white-light LED device of claim 1, wherein the purple light source comprises a red light LED chip and a blue light LED chip connected in series.

14. The white-light LED device of claim 1, wherein the yellow light source comprises a green light LED chip and a red light LED chip connected in series.

15. An illumination method comprising:
disposing at least one purple light source and at least one yellow light source on a base; and
producing white light by mixing the illumination of the yellow light source and the illumination of the purple light source.

16. The illumination method of claim 15, further comprising:
disposing at least one adjusting light source on the base to adjust the color temperature of the white light.

17. The illumination method of claim 16, wherein disposing the purple light source and the yellow light source on the base comprises:
forming the purple light source by connecting at least one red light LED die and at least one blue light LED die in series;
forming the yellow light source by connecting at least one green light LED die and at least one red light LED die in series.

18. The illumination method of claim 16, further comprising:
encapsulating the purple light source, the yellow light source, and the adjusting light source in an encapsulant.

19. A white-light LED device, comprising:
means for providing purple light;
means for providing yellow light; and
means for mixing the purple light and the yellow light to produce white light.

20. The white-light LED device of claim 19, further comprising:
means for adjusting the color temperature of the white light.
